(19) United States
(12) Patent Application Publication
(10) Pub. No.: US 2020/0181768 A1
(43) Pub. Date: Jun. 11, 2020

(54) TRANSITION METAL DICHALCOGENIDE THIN FILM, METHOD FOR MANUFACTURING THE SAME AND DISPLAY DEVICE COMPRISING THE SAME

(71) Applicant: KOREA ADVANCED INSTITUTE OF SCIENCE AND TECHNOLOGY, Daejeon (KR)

(72) Inventors: Sung-Yool CHOI, Daejeon (KR); Gi Woong SHIM, Daejeon (KR); Woonggi HONG, Daejeon (KR)

(73) Assignee: KOREA ADVANCED INSTITUTE OF SCIENCE AND TECHNOLOGY, Daejeon (KR)

(21) Appl. No.: 16/226,857

(22) Filed: Dec. 20, 2018

(30) Foreign Application Priority Data
Dec. 10, 2018 (KR) 10-2018-0157881

(51) Int. Cl. C23C 16/22; H01L 29/66; H01L 29/786; H01L 21/02

(52) U.S. Cl. CPC C23C 16/22; H01L 29/66742; H01L 21/0262; H01L 21/02587; H01L 29/786

(57) ABSTRACT

Provided is a method for manufacturing a transition metal dichalcogenide (TMDC) thin film, which includes: a step of injecting two or more transition metal dichalcogenide precursors into a reactor equipped with a substrate in vapor phase; and a step of forming a transition metal dichalcogenide thin film on the substrate by decomposing the transition metal dichalcogenide precursors under an oxygen condition.

### CROSS-REFERENCE TO RELATED APPLICATION

This application claims priority to and the benefit of Korean Patent Applications No. 10-201 8-0157881 filed on Dec. 10, 2018, the disclosure of which is incorporated herein by reference in its entirety.

This research was supported by Creative Materials Discovery Program through the National Research Foundation of Korea(NRF) funded by Ministry of Science and ICT(2016M3D1A1900035).

### TECHNICAL FIELD

The present disclosure relates to a transition metal dichalcogenide (TMDC) thin film, a method for manufacturing the same and a display device containing the same, more particularly to a transition metal dichalcogenide (TMDC) thin film having significantly improved crystallinity, etc. by using oxygen, a method for manufacturing the same and a display device containing the same.

### BACKGROUND ART

Transition metal dichalcogenides (TMDCs) are drawing attentions as the materials for next-generation electronic devices. They are drawing attentions as channel materials for transparent, flexible display TFTs, channel materials for overcoming the scales of electronic devices, high-sensitivity electronic sensor materials, etc. due to thin film thickness, high mobility (tens to hundreds of cm²/V·s) and high on/off ratio.

But, for application to electronic materials requiring high quality, the development of a large-area, high-quality, high-reliability growth technique is necessary. As the large-area growth technique, solid powder-based chemical vapor deposition is the most frequently used due to low cost, convenient process, etc. However, it is not suitable for large-area applications due to powder evaporation and difficulty in reaction rate control.

To overcome this problem, a technology of manufacturing a 4-inch wafer-scale TMDC film (MoS₂, WS₂) by metalorganic chemical vapor deposition (MOCVD) was disclosed (High-mobility three-atom-thick semiconducting films with wafer-scale homogeneity, Nature 520, 656-660 (2015)). However, it has limitations in that the manufacturing process takes time and the crystallinity is low.

### DISCLOSURE

### Technical Problem

The present disclosure is directed to providing a new metalorganic chemical vapor deposition method providing high crystallinity with short processing time and a transition metal dichalcogenide thin film with superior characteristics manufactured thereby.

### Technical Solution

The present disclosure provides a method for manufacturing a transition metal dichalcogenide (TMDC) thin film, which includes: a step of injecting two or more transition metal dichalcogenide precursors into a reactor equipped with a substrate in vapor phase; and a step of forming a transition metal dichalcogenide thin film on the substrate by decomposing the transition metal dichalcogenide precursors under an oxygen condition.

In an exemplary embodiment of the present disclosure, the decomposition of the transition metal dichalcogenide precursors under an oxygen condition is conducted by supplying oxygen into the reactor and then increasing temperature.

In an exemplary embodiment of the present disclosure, the supply of oxygen is performed in two steps and the oxygen concentration in the second step is lower than the oxygen concentration in the first step.

In an exemplary embodiment of the present disclosure, the second step is performed at or above the temperature where the transition metal dichalcogenide precursors are decomposed on the substrate and form nuclei.

In an exemplary embodiment of the present disclosure, the second step is performed by supplying oxygen intermittently into the reactor or by reducing the supply amount.

In an exemplary embodiment of the present disclosure, the supply of oxygen is performed in a manner wherein oxygen is not supplied at or above the temperature where the transition metal dichalcogenide precursors are decomposed on the substrate and form nuclei.

The present disclosure provides a transition metal dichalcogenide (TMDC) thin film, which has a crystal size of 80 μm or greater and has grown on a substrate without NaCl.

In an exemplary embodiment of the present disclosure, the transition metal dichalcogenide (TMDC) thin film is manufactured by the method described above.

The present disclosure also provides display device containing the transition metal dichalcogenide (TMDC) thin film described above.

### Advantageous Effects

According to the present disclosure, the quality of a TMDC thin film can be improved greatly by depositing the thin film using the oxidizing gas oxygen instead of the reducing gas hydrogen. In particular, nucleation density is reduced greatly by remarkably reducing the time of nuclei (e.g., MoOₓS_{y}) formation during the growth of the TMDC thin film through a process wherein oxygen is supplied intermittently. This enables the synthesis of a TMDC thin film having very high crystallinity by inhibiting the ‘embryonic nucleation’ of oxygen.

### BRIEF DESCRIPTION OF DRAWINGS

The patent or application file contains a least one drawing executed in color. Copies of this patent or patent application publication with color drawing(s) will be provided by the Office upon request and payment of the necessary fee.

FIG. 1 shows the steps of a method for manufacturing a transition metal dichalcogenide thin film according to an exemplary embodiment of the present disclosure.

FIG. 2 schematically shows an apparatus for manufacturing a thin film according to an exemplary embodiment of the present disclosure.

FIGS. 3 and 4 illustrate the oxygen supply method and result of a process for manufacturing a thin film according to an exemplary embodiment of the present disclosure.

FIG. 5 shows the change in oxygen concentration depending on time calculated through transport phenomena simulation.

FIG. 6 shows the optical images of MoS₂ grown by a method according to the present disclosure.

FIG. 7 shows a result of comparing the crystal size of a TMDC thin film according to the present disclosure.

### BEST MODE

The present disclosure is based on the fact that, if a TMDC thin film is deposited using the oxidizing gas oxygen instead of the reducing gas hydrogen, the quality of the thin film can be improved greatly. In addition, nucleation density is reduced greatly by remarkably reducing the time of nuclei (e.g., MoOₓS_{y}) formation during the growth of the TMDC thin film through a process wherein oxygen is supplied intermittently. This enables the synthesis of a TMDC thin film having very high crystallinity by inhibiting the ‘embryonic nucleation’ of oxygen.

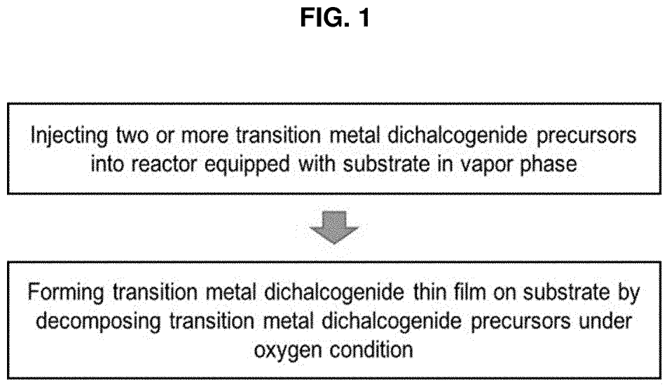

FIG. 1 shows the steps of a method for manufacturing a transition metal dichalcogenide thin film according to an exemplary embodiment of the present disclosure.

Referring to FIG. 1, the method for manufacturing a transition metal dichalcogenide thin film according to an exemplary embodiment of the present disclosure includes: a step of injecting two or more transition metal dichalcogenide precursors into a reactor equipped with a substrate in vapor phase; and a step of forming a transition metal dichalcogenide thin film on the substrate by decomposing the transition metal dichalcogenide precursors under an oxygen condition.

In an exemplary embodiment of the present disclosure, the step of supplying oxygen is performed in two steps. The oxygen concentration in the reactor is different in the first step and the second step. The oxygen concentration in the second step is lower than the oxygen concentration in the first step.

Alternatively, the supply of oxygen may be stopped during the step of forming the transition metal dichalcogenide thin film. That is to say, according to the present disclosure, nucleation density can be reduced greatly by remarkably reducing the time of nuclei (e.g., MoOₓS_{y}) formation during the growth of the TMDC thin film through a process wherein oxygen is supplied with a sufficient concentration in the early step, rather than uniformly throughout the whole thin film formation process.

Hereinafter, a method for manufacturing a MoS₂ thin film as a TMDC thin film according to an exemplary embodiment of the present disclosure is described in detail.

### EXAMPLE

A SiO₂ (90 nm)/Si wafer was cut to a size of 1.5×1.5 cm² and the substrate was ultrasonicated for 15 minutes in acetone and for 15 minutes in isopropyl alcohol (IPA) to remove fine particles on the substrate. Then, in order to induce a hydrophilic surface favorable for substrate growth, the substrate was cleaned with a piranha solution (sulfuric acid 3:hydrogen peroxide 1, v:v). The cleaned substrate was to an alumina boat and then loaded in the center portion of a 2-inch tube furnace.

Then, NaCl which serves to adsorb steam and carbon was added to an alumina bowl and then loaded at the inlet side of the furnace.

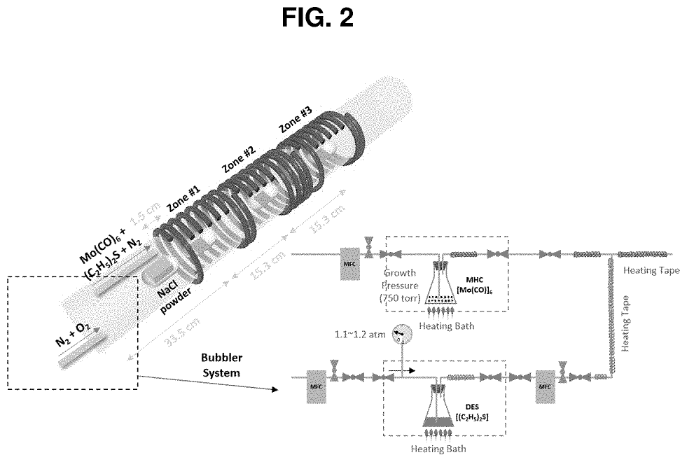

10 mg of Mo(CO)₆ (Sigma-Aldrich, 99.9% trace metals basis, CAS No. 577766) and 30 mL of (C₂H₅)₂S (Sigma-Aldrich, 98%, CAS No. 107247) were loaded into two Erlenmeyer flasks respectively and were supplied using a N₂ bubbling system (see FIG. 2). Then, the gas remaining in the tube furnace was removed as much as possible by purging several times with 1000 sccm of N₂ gas.

A process for manufacturing a thin film according to an exemplary embodiment of the present disclosure may be performed at ambient pressure or low pressure. The desired pressure was achieved using a pressure controller. After reaching the desired pressure, the furnace was heated while flowing the reaction gases.

As the reaction gases, 100 sccm of N₂ was supplied to the Mo(CO)₆ side through bubbling ((Mo(CO)₆ vapor pressure: 0.080 sccm), 10 sccm of N₂ was supplied to the (C₂H₅)₂S side through bubbling ((C₂H₅)₂S vapor pressure: 0.635 sccm), 200 sccm of N₂ was used as a carrier gas and 10 sccm of O₂ was used to create an oxidizing atmosphere. The peak temperature was reached about 20 minutes later, when the oxygen concentration was maintained low to prevent excessive etching of the growing transition metal dichalcogenide. That is to say, in the present disclosure, the effect of the process of the present disclosure was maximized by changing the oxygen concentration after a predetermined time differently from the initial oxygen concentration. For this, the supply of oxygen may be stopped or the oxygen concentration may be maintained at 1 sccm or lower after a predetermined time (e.g., 20 minutes). Alternatively, the oxygen may be flown intermittently until the reaction is completed.

The temperature was increased from room temperature to 600° C. for about 20 minutes until the peak temperature was reached. The peak temperature was maintained for 20 minutes. After the process was completed, the furnace was cooled by opening the cover. With the supply of the reaction gases stopped, N₂ was flown at 1000 sccm to maintain an inert atmosphere.

FIG. 2 schematically shows an apparatus for manufacturing a thin film according to an exemplary embodiment of the present disclosure.

Referring to FIG. 2, the precursors Mo(CO)₆ and (C₂H₅)₂S necessary for the reaction exist in solid and liquid states, respectively. Because 2D layer-by-layer growth is achieved only when the precursors are supplied in trace amounts, the precursors were supplied through a bubbling system instead of direct heating. Because the precursors are volatile materials with high vapor pressures, if the precursors are held in an Erlenmeyer flask, they exist with predetermined fractions in vapor phase. By supplying the carrier gas N₂ thereto, the precursors can be supplied in trace amounts through pushing.

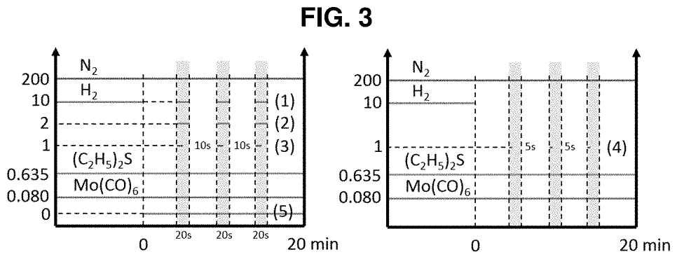

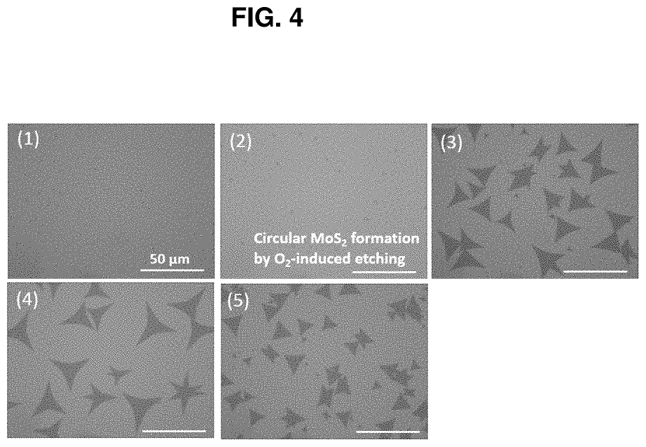

FIGS. 3 and 4 illustrate the oxygen supply method and result of a process for manufacturing a thin film according to an exemplary embodiment of the present disclosure. In FIG. 3, the Y-axis represents gas flow rate and the X-axis represents time. The numbers in the parentheses in FIGS. 3 and 4 represent reaction conditions.

Referring to FIG. 3, oxygen was supplied under the conditions of (1)-(5) ((1): 3 times for 20 seconds at 10 sccm, (2): 3 times for 20 seconds at 2 sccm, (3): 3 times for 10 seconds at 1 sccm, (4): 3 times for 5 seconds at 1 sccm, (5): no oxygen flow.

The furnace temperature was raised from room temperature to 600° C. from 0 to 20 minutes and the temperature was maintained at 600° C. from 20 to 40 minutes. Referring to FIG. 4, it can be seen that, even when oxygen is supplied intermittently, etching of the thin film occurs instead of growth if the oxygen concentration is above a certain level.

To describe in more detail, an oxidizing atmosphere is created as oxygen is supplied initially for 20 minutes. When temperature at which the reaction is initiated (600° C.) is reached, the reaction is initiated as the oxygen present in the reactor decomposes the precursors. At the same time, reaction byproducts are removed through etching. That is to say, in the present disclosure, the oxygen is supplied in a relatively large amount in the first step at least during the initiation of the reaction and, after a predetermined time (e.g., after a predetermined time has passed since the reaction temperature was reached), the supply of oxygen is stopped (see (5) of FIG. 3) or the oxygen is maintained at a very low concentration or is flown intermittently (see (1)-(4) of FIG. 3). Due to the characteristics of the reactor (quasi-closed system), the decrease in oxygen supply at the peak temperature leads to rapid decrease in the concentration of oxygen remaining in the reactor owing to the reaction.

Meanwhile, the oxygen reacts with the precursors to form core-shell type MoOₓS_{y} nuclei. As the oxygen concentration is decreased rapidly, the time during which the nucleation is possible becomes very short.

As a result, the nucleation density, which is proportional to the integral of nucleation rate over time, becomes very low. In addition, the nuclear etching effect by the oxygen can be prevented.

Due to the low nuclear density, the size of MoS₂ crystals growing therefrom is increased greatly. Although 02 provides an effect of improving film quality by removing atomic-scale bonds present on the thin film, the thin film may be etched if the oxygen concentration is maintained very high (see (1) and (2) of FIG. 4). Therefore, it is important to lower the oxygen concentration after the reaction temperature has been reached (see (3), (4) and (5) of FIG. 4).

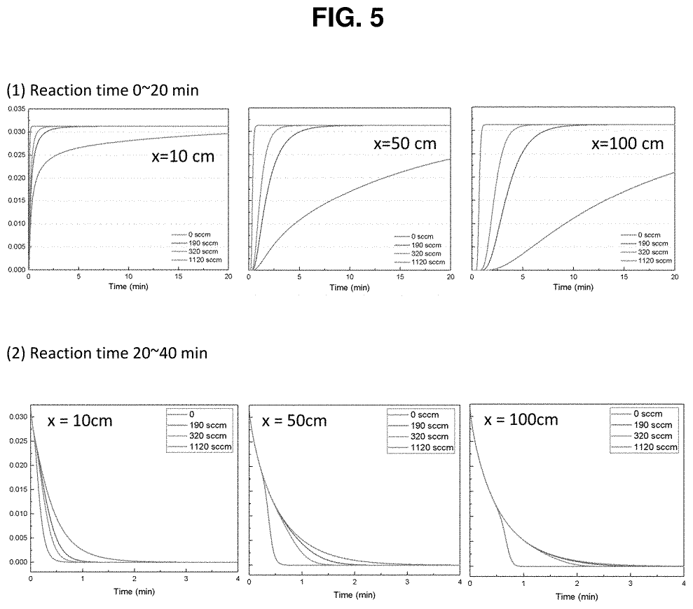

FIG. 5 shows the change in the oxygen concentration depending on time calculated through transport phenomena simulation.

Referring to FIG. 5, the simulation was conducted with actual dimensions, flow rate and temperature assuming that the furnace was a cylindrical reactor.

The horizontal dimension of the furnace was 100 cm and the change in the oxygen concentration depending on location was estimated as shown in the graphs. In the graphs, the values represented in the sccm unit are the flow rate of nitrogen used as the carrier gas. It can be seen that the oxygen was almost depleted within about 1-3 minutes at the peak temperature (reaction time: 20-40 minutes). This demonstrates that nucleation occurs in very short time when oxygen supply is interrupted at the peak temperature. Therefore, in the present disclosure, a TMDC thin film with very high quality is prepared by inducing oxygen depletion by using the transport phenomena in the MOCVD-TMDC system, thereby maintaining the nucleation time very short.

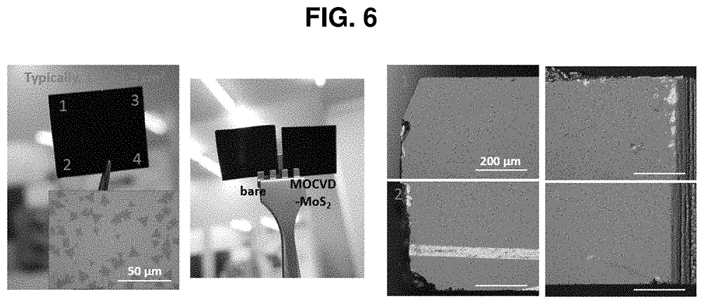

FIG. 6 shows the optical images of MoS₂ grown by the method according to the present disclosure.

Referring to FIG. 6, although the growth of a TMDC thin film is conducted normally in the scale of 1.5×1.5 cm², the process can be extended to large-area applications by increasing the reactor size. In addition, a device having uniform characteristics over the entire substrate can be synthesized through thin film deposition in vapor phase.

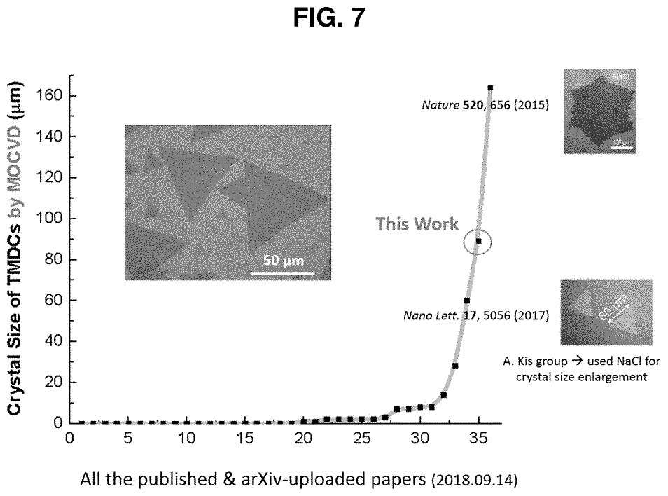

FIG. 7 shows a result of comparing the crystal size of the TMDC thin film according to the present disclosure.

Referring to FIG. 7, unlike the case of using NaCl reported in Nature (2015), the present disclosure enables the preparation of a TMDC thin film having a crystal size of 80 μm or greater without using NaCl. Accordingly, considering that a material with high crystallinity is favorable for application to display devices such as a TFT (thin-film transistor) for displays, the thin film according to the present disclosure can be used as a TFT for displays, etc.

1. A method for manufacturing a transition metal dichalcogenide (TMDC) thin film, comprising:
a step of injecting two or more transition metal dichalcogenide precursors into a reactor equipped with a substrate in vapor phase; and
a step of forming a transition metal dichalcogenide thin film on the substrate by decomposing the transition metal dichalcogenide precursors under an oxygen condition.

2. The method for manufacturing a transition metal dichalcogenide (TMDC) thin film according to claim 1, wherein the decomposition of the transition metal dichalcogenide precursors under an oxygen condition is conducted by supplying oxygen into the reactor and then increasing temperature.

3. The method for manufacturing a transition metal dichalcogenide (TMDC) thin film according to claim 2, wherein the supply of oxygen is performed in two steps and the oxygen concentration in the second step is lower than the oxygen concentration in the first step.

4. The method for manufacturing a transition metal dichalcogenide (TMDC) thin film according to claim 3, wherein the second step is performed at or above the temperature where the transition metal dichalcogenide precursors are decomposed on the substrate and form nuclei.

5. The method for manufacturing a transition metal dichalcogenide (TMDC) thin film according to claim 3, wherein the second step is performed by supplying oxygen intermittently into the reactor or by reducing the supply amount.

6. The method for manufacturing a transition metal dichalcogenide (TMDC) thin film according to claim 2, wherein the supply of oxygen is performed in a manner wherein oxygen is not supplied at or above the temperature where the transition metal dichalcogenide precursors are decomposed on the substrate and form nuclei.

7. A transition metal dichalcogenide (TMDC) thin film, which has a crystal size of 80 μm or greater and has grown on a substrate without NaCl.

8. The transition metal dichalcogenide (TMDC) thin film according to claim 7, wherein the transition metal dichalcogenide (TMDC) thin film is manufactured by the method according to claim 1.

9. A display device comprising the transition metal dichalcogenide (TMDC) thin film according to claim 8.
